(19) United States
(12) Patent Application Publication
(10) Pub. No.: US 2017/0353176 A1
(43) Pub. Date: Dec. 7, 2017

(54) RELAXATION OSCILLATOR

(71) Applicant: Nordic Semiconductor ASA, Trondheim (NO)

(72) Inventors: Ola Bruset, Trondheim (NO); Tor Øyvind Vedal, Trondheim (NO)

(73) Assignee: Nordic Semiconductor ASA, Trondheim (NO)

(21) Appl. No.: 15/537,330

(22) PCT Filed: Dec. 11, 2015
(86) PCT No.: PCT/GB2015/053863

§ 371 Date: Jun. 16, 2017

(30) Foreign Application Priority Data
Dec. 19, 2014 (GB) 1422713.6

(51) Int. Cl. H03K 4/50

(52) U.S. Cl. CPC H03K 4/50

(57) ABSTRACT

A relaxation oscillator 2 comprises:
a comparator 4 comprising:
   a differential pair of transistors 140, 142, 144. 40, 42, 44;
   a static current source 32; and
   a dynamic current source 32; and
at least one energy storage component 8, 14;
   wherein the comparator 4 is arranged to provide an output signal which triggers the charging or discharging of the energy storage component 8, the dynamic current source 32 being enabled prior to the charging or discharging being triggered and disabled after a predetermined time.

This invention relates to relaxation oscillators, particularly those suited to applications where fast switching, low noise and low current consumption is of importance.

Relaxation oscillators, usually implemented with a feedback loop and a switching device (e.g. a comparator or a relay), generate a periodic output signal. These devices produce a non-linear output signal such as a square wave. The principle is that the feedback loop and switching device are used to charge an energy storage device such as a capacitor or an inductor to a threshold level, before discharging it and repeating the charging and discharging cycle. The charging and discharging behaviour produces a periodic, discontinuous waveform that can then be taken as an output.

There are often trade-offs between current consumption and switching speed, and between current consumption and noise in conventional relaxation oscillators. Maintaining a fast switching speed and low noise are important for low jitter operation of a relaxation oscillator (i.e. with only small deviations from the desired frequency) yet typically require higher currents. This conflicts with the requirements of modern battery powered devices, where reducing current consumption is very important. The present invention aims to address this problem.

From a first aspect, the present invention provides a relaxation oscillator comprising:
a comparator comprising:
   a differential pair of transistors;
   a static current source; and
   a dynamic current source; and
at least one energy storage component;
   wherein the comparator is arranged to provide an output signal which triggers the charging or discharging of the energy storage component, the dynamic current source being enabled prior to the charging or discharging being triggered and disabled after a predetermined time.

It will be seen by those skilled in the art that in accordance with the invention a relaxation oscillator can be operated at a first, low static current when charging the energy storage device, before enabling a second, dynamic high current source before the comparator triggers the charging or discharging. This temporarily higher current can advantageously provide more accurate timing, reduce the effect of noise and have lower overall current consumption when compared to conventional relaxation oscillators.

The invention may be implemented with a single energy storage component, However in a set of embodiments a plurality of energy storage components is provided—e.g. two. In such embodiments the output signal may be used to switch between energy storage components so that one may be charging whilst another is discharging. This allows for higher frequency outputs.

The static or dynamic current sources may take any form that is known per se in the art. However, in a set of embodiments, either or both of the current sources is a current mirror. The Applicant has appreciated that it is particularly advantageous to use current mirrors in this context as they are power efficient, and will give a more accurate output frequency, wherein the output frequency is proportional to the current divided by the capacitance.

In a set of embodiments the oscillator is arranged to use a voltage across the energy storage component(s) to enable the dynamic current source. This may facilitate the dynamic current source being enabled just prior to the triggering of the charging/discharging, or switching between energy storage components where a plurality is provided. In a set of embodiments the dynamic current source comprises at least one switching transistor arranged to enable and disable the dynamic current source. In a set of embodiments a gate lead of said switching transistor is connected to the energy storage component. Where a plurality of energy storage components is provided separate switching transistors may be provided, each of which may have a gate lead connected to a respective energy storage component. Providing a transistor with its gate connected to the energy storage device and its source lead connected such that it enables or disables the dynamic current source, may advantageously cause the dynamic current source to switch on at a time just before the comparator triggers any charging or discharging.

There are a number of different transistor technologies that are available for the fabrication of semiconductor devices. However, for low power applications, field effect transistors (FETs) are the most suitable technology due to their low current operating requirements. In a set of embodiments therefore the differential pair and/or the switching transistor(s) comprise field effect transistors.

The invention may be implemented using any energy storage component that is known per se in the art. Preferably however, the or each energy storage component comprises a capacitor. Capacitors are particularly well suited for use in applications where switching speed and power consumption are important.

The output signal from the comparator can be used to control which of a plurality of energy storage components is being charged at any given moment. In some sets of embodiments the relaxation oscillator comprises an energy storage charging control module, which switches between the energy storage components when an appropriate signal is received from the comparator.

When viewed from a second aspect, the invention provides a battery powered integrated circuit comprising a relaxation oscillator as described above.

An embodiment of the present invention will now be described, by way of example only, with reference to the accompanying drawings, in which:

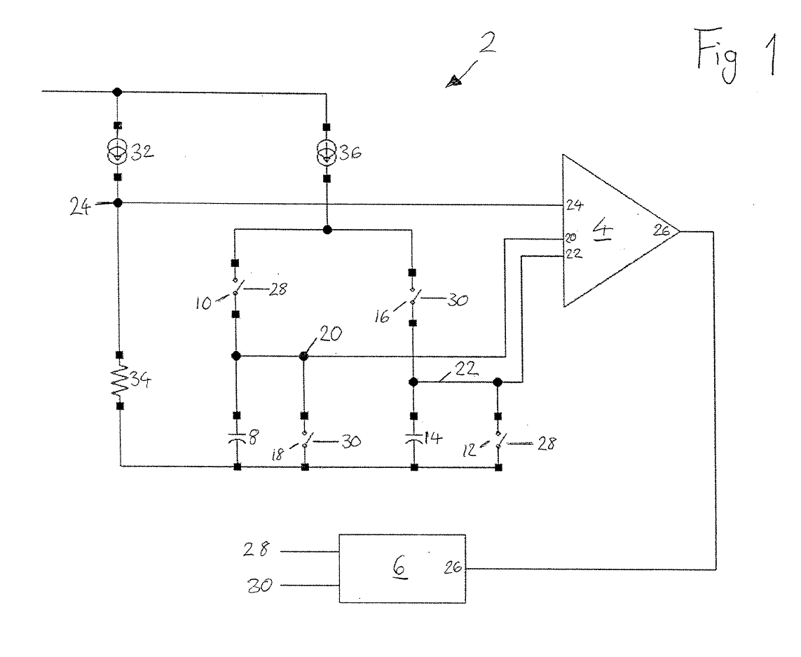

FIG. 1 is a circuit diagram of an exemplary embodiment of the present invention;

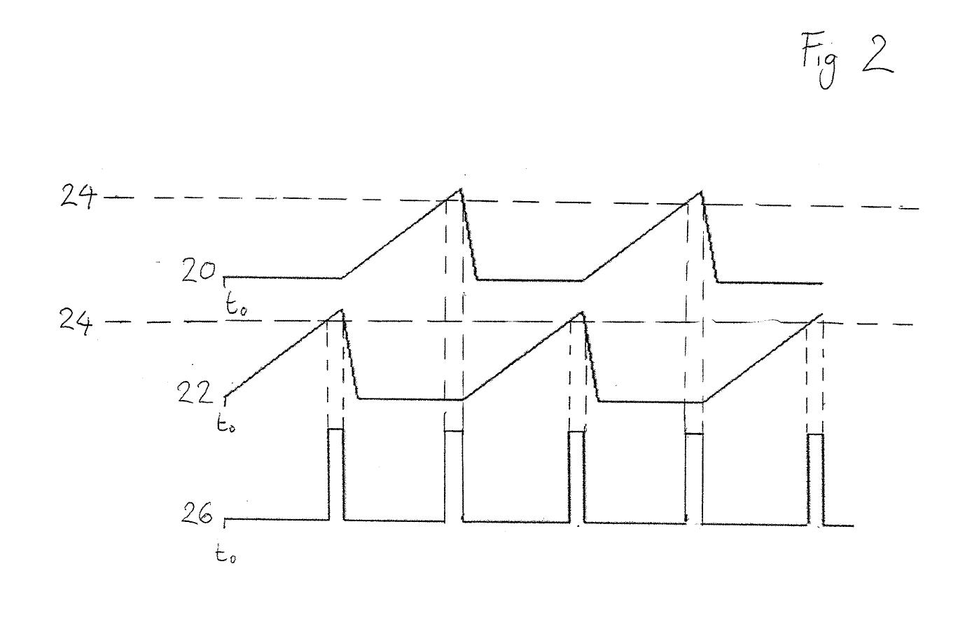

FIG. 2 is a timing diagram of an exemplary embodiment of the present invention;

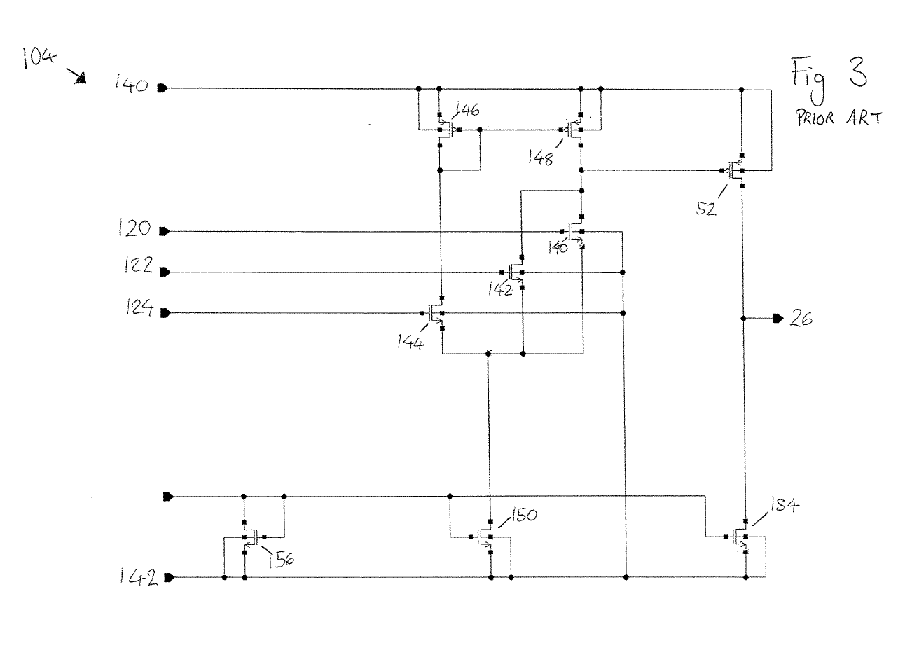

FIG. 3 is a prior art circuit diagram; and

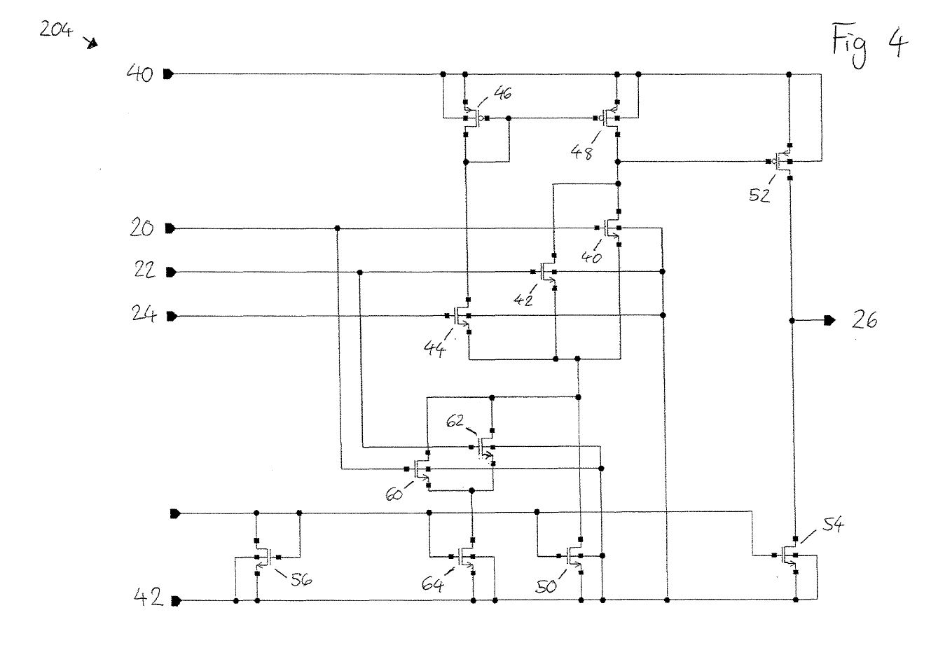

FIG. 4 is a circuit diagram of a comparator that comprises part of an exemplary embodiment of the present invention.

FIG. 1 shows a circuit diagram of an exemplary embodiment of a relaxation oscillator 2 in accordance with the present invention. The relaxation oscillator 2 comprises a comparator 4, two capacitors 8, 14, four switches 10, 12, 16, 18, and a charging control module 6.

The comparator 4 is a three input comparator wherein the three inputs are the capacitor voltages 20, 22 and a reference voltage 24. The comparator produces an output signal 26 that is taken as an input by the charging control module 6. The charging control module produces two actuation signals 28, 30 that control the switches 10, 12, 16, 18.

A first current source 32 produces a constant current through a fixed resistor 34, which due to Ohm's law produces a fixed potential difference across the resistor 34. This potential difference is taken as the voltage reference 24 that is then used as one of the inputs to the comparator 4 as outlined above.

A second current source 36 produces a constant current that is used to charge either the first capacitor 8 or the second capacitor 14, depending on the state of the circuit and which of the switches 10, 12, 16, 18 are closed at any given time.

The comparator 4 compares the two capacitor voltages 20, 22 to the reference voltage 24, and determines if either one of the two capacitor voltages 20, 22 is greater than the reference voltage 24. If one of the capacitor voltages 20, 22 exceeds the reference voltage 24, the output voltage 26 is set to logic high; else it remains at logic low.

The charging control module 6 is arranged so that at any given time one of the first actuation signal 28 and the second actuation signal 30 is high and the other is low. The control module 6 monitors the output signal 26 and whenever a positive edge arises on it, the charging control module 6 swaps which one of the signals 28, 30 is high and which one is low.

When the first actuation signal 28 goes high, the first switch pair 10, 12 is closed and the second switch pair 16, 18 is opened, connecting the first capacitor 8 to the second current source 36, and short-circuiting the second capacitor 14. When the second actuation signal 30 goes high, the first switch pair 10, 12 is opened and the second switch pair 16, 18 is closed, connecting the second capacitor 14 to the second current source 36, and short-circuiting the first capacitor 8.

Basic operation of the oscillator will now be described with reference to FIG. 2 which is a timing diagram of the embodiment of FIG. 1. At an initial time t₀, the second switch pair 16, 18 are closed, and thus the second capacitor 14 is connected to the second current source 36. This causes the second capacitor 14 to charge, and consequentially the second capacitor voltage 22 rises.

Once the second capacitor voltage 22 exceeds the reference voltage 24, the comparator output signal 26 changes to logic high. Subsequently, the charging control unit 6 detects the logic high on the output signal 26, changes the state of the two switch pairs 10, 12, 16, 18 such that the first capacitor 8 begins to charge and the second capacitor 14 discharges. As a result, the first capacitor voltage 20 begins to rise, while the second capacitor voltage 22 rapidly declines. Once the second capacitor voltage 22 no longer exceeds the reference voltage 24, the comparator output voltage 26 changes back to logic low.

The cycle continues, with each capacitor 8, 14 charging until it exceeds the reference voltage 24 before the output signal 26 is pulsed high and the roles of the capacitors swap. This repetitive pattern of charging and discharging cycles gives rise to a periodic, non-linear output signal 26.

FIG. 3 is a prior art circuit diagram of a comparator 104 comprising a static current source that could have been used in the relaxation oscillator of FIG. 1 and which is described for reference purposes only. The comparator 104 would take as inputs two capacitor voltages 120, 122 and a reference voltage 124 and provide an output voltage 126.

The comparator of FIG. 3 comprises three NMOS transistors 140, 142, 144 with their respective gate leads connected to the two capacitor voltages 120, 122, and the reference voltage 124 respectively. These three transistors 140, 142, 144 are arranged as a variant of a differential pair circuit. The reference transistor 144 forms one half of the differential pair, while the capacitor-connected transistors 140, 142 are arranged in parallel and jointly form the other half of the differential pair. This arrangement permits the comparator to compare either of the two capacitor voltages 120, 122 to the reference voltage 124. This differential pair arrangement is connected to the positive supply rail V_{DD} 40 via a current mirror or active load arrangement comprising two transistors 146, 148.

The differential pair comprising the capacitor- and reference-connected transistors 140, 142, 144 is arranged as a long tailed pair. The tail of the long tailed pair that provides a bias current is provided in this arrangement by the tail transistor 150. This tail transistor 150 provides a constant, static current source for the operation of the differential pair.

A single sided output is taken from the differential pair and connected to the gate lead of a PMOS transistor 152 that forms a push-pull output stage with an NMOS transistor 154. This push-pull output stage causes the comparator output signal 126 to saturate to logic high or logic low at all times, depending on the single sided output from the differential pair at any given time.

FIG. 4 is a circuit diagram of an alternative comparator 204 in accordance the present invention. The topology of this arrangement is similar to that in FIG. 3 (and similar reference numerals are used for similar parts except for omission of the leading 1). However it advantageously adds an additional current source to the differential pair arrangement, in the form of a second tail 64 in parallel with a first tail transistor 50.

Two NMOS dynamic current source transistors 60, 62 are arranged in parallel with their respective source and drain leads connected together, with the drain leads further connected to the source leads of the differential pair transistors 40, 42, 44, and the source leads of the dynamic current source transistors 60, 62 connected to the second tail transistor 64. The gate leads of the dynamic current source transistors 60, 62 are each connected to the first and second capacitor voltages 20, 22 respectively.

This advantageous arrangement allows for a second dynamic current source, comprising the dynamic current source transistors 60, 62 and the second tail transistor 64, to be selectively enabled and disabled to provide additional current to the differential pair when required. When either one of the capacitor voltages 20, 22 is sufficiently high, the respective dynamic current source transistor 60, 62 will be switched on and connect the differential pair to the additional tail transistor 64 that provides additional current just before the comparator will change the output signal 26 to a logic high. This ensures a clean pulse with accurate timing and reduces the effect of noise, while maintaining low average power consumption.

Thus it will be seen that a relaxation oscillator particularly suited to applications where timing, noise and power considerations are particularly important has been described. Although a particular embodiment has been described in detail, many variations and modifications are possible within the scope of the invention.

1. A relaxation oscillator comprising:
a comparator comprising:
a differential pair of transistors;
a static current source; and
a dynamic current source; and
at least one energy storage component;
wherein the comparator is arranged to provide an output signal which triggers the charging or discharging of the energy storage component, the dynamic current source being enabled prior to the charging or discharging being triggered and disabled after a predetermined time.

2. The relaxation oscillator as claimed in claim 1 comprising a plurality of energy storage components.

3. The relaxation oscillator as claimed in claim 2 wherein the output signal is used to switch between energy storage components so that one may be charging whilst another is discharging.

4. The relaxation oscillator as claimed in claim 1 wherein either or both of the current sources is a current mirror.

5. The relaxation oscillator as claimed in claim 1 wherein the oscillator is arranged to use a voltage across the energy storage component(s) to enable the dynamic current source.

6. The relaxation oscillator as claimed in claim 1 wherein the differential pair comprises field effect transistors.

7. The relaxation oscillator as claimed in claim 1 wherein the dynamic current source comprises at least one switching transistor arranged to enable and disable the dynamic current source.

8. The relaxation oscillator as claimed in claim 7 wherein a gate lead of said switching transistor is connected to the energy storage component.

9. The relaxation oscillator as claimed in claim 7 wherein the switching transistor(s) comprise field effect transistors.

10. The relaxation oscillator as claimed in claim 1 wherein the or each energy storage component comprises a capacitor.

11. The relaxation oscillator as claimed in claim 1 comprising an energy storage charging control module.

12. A battery powered integrated circuit comprising the relaxation oscillator as claimed in claim 1.
